(19) United States
(12) Patent Application Publication
(10) Pub. No.: US 2026/0032961 A1
(43) Pub. Date: Jan. 29, 2026

(54) ISOLATION STRUCTURES FOR SOURCE/DRAIN REGIONS IN NANOSTRUCTURE TRANSISTORS

(71) Applicant: Taiwan Semiconductor Manufacturing Company, Ltd., Hsinchu (TW)

(72) Inventors: Ching-Pai HSU, New Taipei City (TW); Tsung-Yu CHIANG, New Tapei City (TW)

(73) Assignee: Taiwan Semiconductor Manufacturing Company, Ltd., Hsinchu (TW)

(21) Appl. No.: 18/787,559

(22) Filed: Jul. 29, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 84/0151; H10D 84/038; H10D 84/83

(57) ABSTRACT

The present disclosure is directed to a structure of a gate-all-around field effect transistors (GAAFET) on a substrate and a method of forming the structure. The structure includes isolation layers below S/D epitaxial structures of the GAAFET. The isolation layers include silicon oxide and are formed by a flowable chemical vapor deposition process. The isolation layers are disposed over side surfaces of bottommost inner spacer structures of the GAAFET and protrude into the substrate. The isolation layers suppress a leakage current through the substrate between opposite S/D epitaxial structures. The isolation layers also suppress a leakage current through the bottommost inner spacer structures between a gate structure of the GAAFET and the S/D epitaxial structures.

### BACKGROUND

Gate-all-around (GAA) field effect transistors (GAAFETs), such as nano-sheet or nano-wire GAAFETs, have improved gate control over their channel regions compared to other types of FETs whose gate structures cover sidewall portions and top surfaces of semiconductor fin structures. Due to their gate-all-around geometry, GAA nano-sheet and nano-wire FETs achieve larger effective channel widths and higher drive currents.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 is an isometric view of a semiconductor device including nanostructure transistors, in accordance with some embodiments.

FIG. 2 is a cross-sectional view of a semiconductor device including nanostructure transistors, in accordance with some embodiments.

FIG. 3A-3C are cross-sectional views of a zoom-in region of a semiconductor device including nanostructure transistors, in accordance with some embodiments.

FIG. 4 is a flowchart of a method for the formation of isolation structures for source/drain epitaxial structures of nanostructure transistors, in accordance with some embodiments.

FIGS. 5 and 6 are isometric views of intermediate structures during the fabrication of isolation structures for source/drain epitaxial structures of nanostructure transistors, in accordance with some embodiments.

FIGS. 7 through 17 are cross-sectional views of intermediate structures during the fabrication of isolation structures for source/drain epitaxial structures of nanostructure transistors, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

By way of example and not limitation, nanostructure transistors, like GAA nano-sheet (NS) or nano-wire (NW) FETs (collectively referred to as “GAAFETs”) with nano-sheet (NS) or nano-wire (NW) channel regions, can be formed as follows. A fin-like structure with alternating silicon-germanium (SiGe) and silicon (Si) NS or NW layers is formed on a substrate (e.g., on semiconductor substrate). A sacrificial gate structure is then formed on a middle portion of the fin-like structure to cover top and sidewall surfaces of the fin-like structure so that edge portions of the fin-like structure are not covered by the sacrificial gate structure. The edge portions of the fin-like structure not covered by the sacrificial gate structure are removed. Subsequently, edge portions of the SiGe NS or NW layers are recessed with respect to edge portions of the Si NS or NW layers, and an inner spacer structure is formed by depositing a dielectric material to fill the space formed by the etched portions of the SiGe NS or NW layers. Source/drain (S/D) epitaxial structures are then formed to abut (or to be in contact with) edge portions of the fin-like structures so that the S/D epitaxial structures are in contact with the Si NS or NW layers and isolated (or separated) from the SiGe NS or NW layers by the inner spacer structures. Source/drain may refer to a source or a drain, individually or collectively dependent upon the context. At a later operation, the sacrificial gate structure is removed to expose the top and sidewall surfaces of the fin-like structure. The SiGe NS or NW layers are selectively removed from the fin-like structure. During the selective removal process, the Si NS or NW layers and the inner spacer structures are not removed. Subsequently, a metal gate structure is formed to surround the Si NS or NW layers. Similar to the SiGe NS or NW layers prior to their selective removal, the metal gate structure is isolated (or separated) from the S/D epitaxial structures through the inner spacer structures.

The structure of the GAAFETs may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

As semiconductor devices continue scaling down, in the exemplary GAAFET formed by the process described above, critical dimensions of the GAAFET, such as lengths/widths of the Si NS or NW layers as channels are getting smaller. The channels can be formed by removing portions of the SiGe and Si NS or NW layers to form openings with high aspect ratios in the fin-like structure. Challenging issues arise during the formation of the openings due to their high aspect ratios. In particular, among the SiGe NS or NW layers, the bottommost SiGe NS or NW layers may have less uniform shapes (e.g., having uneven thicknesses and/or lengths), compared with their counterparts above them. When the SiGe NS or NW layers are subsequently replaced by the gate structures, the bottommost gate structures may accordingly have less uniformed shapes. As a consequence, the channel regions in the substrate and under the bottommost gate structures can have less effective gate-control, thus forming leakage current channels between opposite S/D epitaxial structures of the GAAFET. In addition, the bottommost SiGe NS or NW layers with less uniform shapes may also affect the geometry of the adjacent bottommost inner spacers, which may cause leakage currents between the S/D epitaxial structures and the bottommost gate structures.

The embodiments described herein are directed to overcome the challenges mentioned above. In some embodiments, a GAAFET can include isolation layers below the S/D epitaxial structures of the GAAFET. The isolation layers can include silicon oxide and can be formed by a flowable chemical vapor deposition (FCVD) process. The isolation layers can be disposed over side surfaces of the bottommost inner spacer structures of the GAAFET and protrude into the substrate. The isolation layers can suppress the leakage current through the substrate between the opposite S/D epitaxial structures. The isolation layers can also suppress the leakage current through the bottommost inner spacer structures between the gate structure of the GAAFET and the S/D epitaxial structures. In addition, the isolation layers can improve a gate capacitance between the gate structure of the GAAFET and the S/D epitaxial structures.

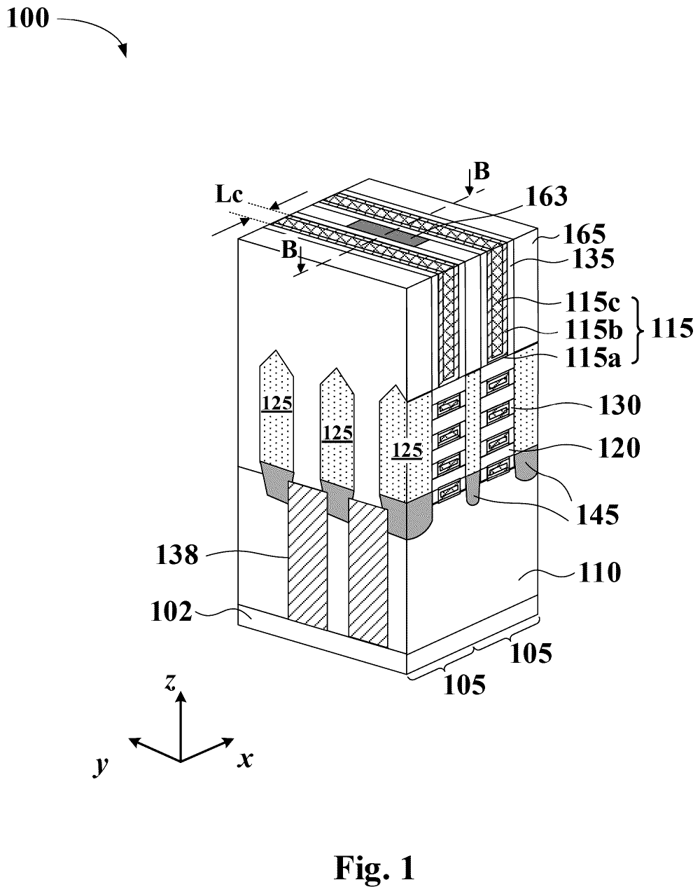

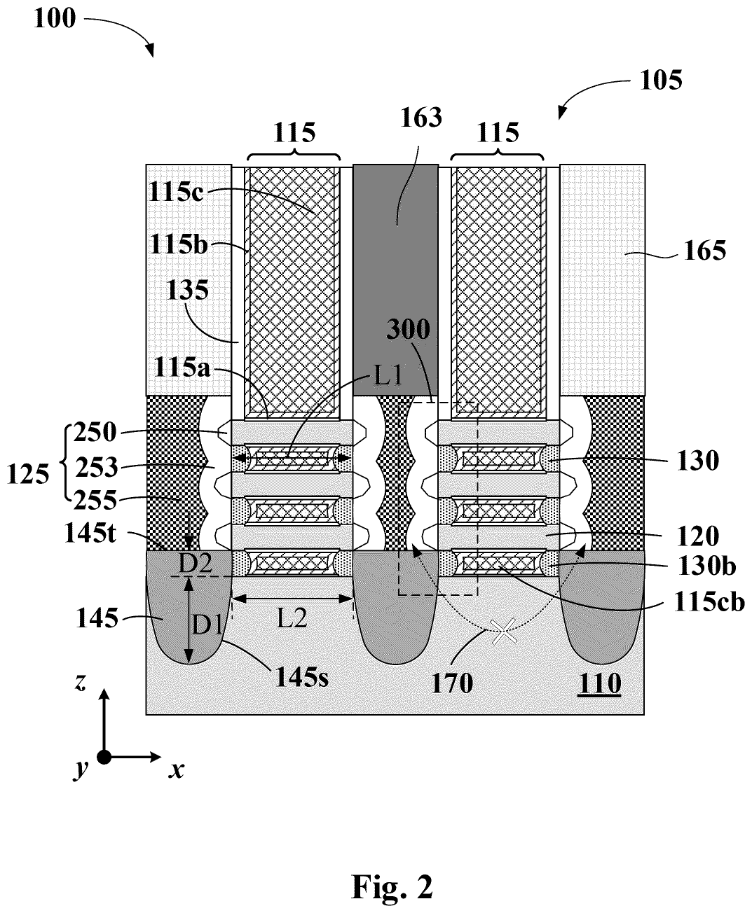

A semiconductor device 100 having multiple GAAFETs 105 formed over a substrate 102 is described with reference to FIGS. 1 and 2, according to some embodiments. FIG. 1 illustrates an isometric view of semiconductor device 100, according to some embodiments. Semiconductor device 100 can be included in a microprocessor, memory cell, or other integrated circuit (IC). FIG. 2 illustrates cross-sectional (e.g., along the x-z plane) view of semiconductor device 100 along line B-B of FIG. 1, according to some embodiments.

Referring to FIG. 1, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

Although FIGS. 1 and 2 show fin structure 110 accommodating two GAAFETs 105, any number of GAAFETs 105 can be disposed along fin structure 110. In some embodiments, GAAFET 105 can include multiple fin structures 110 extending along a first horizontal direction (e.g., in the x-direction) and gate structure 115 traversing through the multiple fin structures 110 along a second horizontal direction (e.g., in the y-direction). In some embodiments, a crystal orientation of fin structures 110 can be the same as the crystal orientation of substrate 102.

Referring to FIGS. 1 and 2, one or more nano-sheet (NS) layers 120 can be disposed over fin structure 110. Each NS layer 120 can be wrapped by gate structure 115 to function as GAAFET 105's channel. For example, a top surface, side surfaces, and a bottom surface of each NS layer 120 can be surrounded and in physical contact with gate structure 115. Fin structure 110 and NS layer 120 can be made of materials similar to (e.g., lattice mismatch within about 5%) substrate 102. In some embodiments, a crystal orientation of NS layer 120 can be the same as the crystal orientation of fin structures 110. In some embodiments, each of fin structure 110 and NS layer 120 can be made of Si or SiGe. Each of fin structure 110 and NS layer 120 can be un-doped, doped with p-type dopants, doped with n-type dopants, or doped with intrinsic dopants. In some embodiments, fin structure 110 and NS layers 120 can be doped together with p-type dopants or with n-type dopants. Although FIG. 1 shows that each GAAFET 105 includes four NS layers 120 and FIG. 2 shows that each GAAFET 105 includes three NS layers 120, any number of NS layers 120 can be included in each GAAFET 105. For example, each GAAFET 105 can include one, two, five, or six NS layers 120.

Referring to FIGS. 1 and 2, gate structures 115 can be a multilayered structure that wraps around each NS layer 120 to modulate GAAFET 105. Gate structures 115 can have a length Lc representing GAAFET 105's channel length. Length Lc can have any suitable horizontal (e.g., in the x-direction) dimension, such as from about 3 nm to about 200 nm. In some embodiments, a height of gate structures 115 along a vertical direction (e.g., in the z-direction) above fin structure 110 can be between about 12 nm and about 14 nm. In some embodiments, the height of gate structures 115 above fin structure 110 can be greater than about 14 nm. By way of example and not limitation, each gate structure 115 can include a dielectric stack formed by an interfacial dielectric layer 115a and a gate dielectric layer 115b. Further, each gate structure 115 includes a gate electrode 115c with capping layers, one or more work function metallic layers, and a metal fill not individually shown in FIG. 1 for simplicity. Gate dielectric layer 115b can include any suitable dielectric material with any suitable thickness that can provide channel modulation for GAAFET 105. In some embodiments, gate dielectric layer 115b can be made of silicon oxide or a high-k dielectric material (e.g., hafnium oxide or aluminum oxide). In some embodiments, gate dielectric layer 115b can have a thickness ranging from about 1 nm to about 5 nm. Based on the disclosure herein, other materials and thicknesses for gate dielectric layer 115b are within the scope and spirit of this disclosure. Gate electrode 115c can function as a gate terminal for GAAFET 105. Gate electrode 115c can include any suitable conductive material that provides a suitable work function to modulate GAAFET 105. In some embodiments, gate electrode 115c can be made of titanium nitride, tantalum nitride, tungsten nitride, titanium, aluminum, copper, tungsten, tantalum, copper, or nickel. Based on the disclosure herein, other materials for gate electrode 115c are within the scope and spirit of this disclosure.

Referring to FIGS. 1 and 2, S/D epitaxial structures 125 can be disposed over opposite sides (e.g., along the x-direction) of each NS layer 120 to function as GAAFET 105's source and drain terminals. S/D epitaxial structures 125 can be disposed on fin structures 110. In some embodiments, S/D epitaxial structures 125 can be disposed above isolation layers 145 on fin structures 110, such that S/D epitaxial structures 125 and fin structures 110 are electrically isolated. S/D epitaxial structure 125 can be made of an epitaxially-grown semiconductor material similar to (e.g., lattice mismatch within about 5%) NS layer 120. In some embodiments, S/D epitaxial structures 125 can be made of Si, Ge, SiGe, InGaAs, or GaAs. S/D epitaxial structures 125 can be doped with p-type dopants, n-type dopants, or intrinsic dopants. In some embodiments, S/D epitaxial structures 125 can have a different doping type from NS layer 120. In some embodiments, the n-type dopants in S/D epitaxial structure 125 can include P, As, Sb, and/or a combination thereof. In some embodiments, a crystal orientation of S/D epitaxial structure 125 can be the same as the crystal orientation of NS layer 120.

Each S/D epitaxial structure 125 can include epitaxial regions 250, 253, and 255, as shown in FIG. 2. Epitaxial regions 250, 253, and 255 can be formed in different stages during an epitaxial process. Epitaxial regions 250 can be epitaxially grown from side surfaces of NS layers 120 and extending in a horizontal direction (e.g., along the x-axis) and isolated with each other. Each epitaxial region 250 can have a vertical interface with an NS layer 120 and tilted or curved surfaces opposite to the vertical interface. Epitaxial regions 253 can be epitaxially grown from the tilted or curved surfaces of epitaxial regions 250. Each S/D epitaxial structure 125 can include two epitaxial regions 253 disposed on the two sides of S/D epitaxial structure 125. Each epitaxial region 253 can be a continuous epitaxial layer connecting all epitaxial regions 250 vertically disposed on one of the two sides of S/D epitaxial structure 125. Epitaxial regions 255 can be epitaxially grown from side surfaces of epitaxial regions 253 and can extend in a vertical direction (e.g., along the z-axis). Each epitaxial region 255 can connect the two epitaxial regions 253 within each S/D epitaxial structure 125. In some embodiments, a distance L1 between two S/D epitaxial structures 125 on opposite sides of a GAAFETs 105 can be between about 5 nm and about 250 nm. In some embodiments, doping concentrations of epitaxial regions 250, 253, and 255 can be different. For example, the doping concentration of epitaxial regions 255 can be greater than the doping concentration of epitaxial regions 253, and the doping concentration of epitaxial regions 253 can be greater than the doping concentration of epitaxial regions 250. In some embodiments, the relatively lower doping concentration of epitaxial regions 250 can prevent unwanted diffusion of dopants into NS layers 120 that may compromise a conductivity of NS layers 120. In some embodiments, the relatively higher doping concentration of epitaxial region 255 can reduce a contact resistance between S/D contacts 163 and S/D epitaxial structure 125.

Referring to FIGS. 1 and 2, semiconductor device 100 can include inner spacer structures 130 abutting (or in contact with) side surfaces of gate structures 115. Inner spacer structures 130 can separate gate structures 115 from S/D epitaxial structures 125. For example, inner spacer structures 130 can be formed at gate structures 115's opposite sides along GAAFETs 105's channel direction (e.g., along the x-direction) to separate gate structures 115 from S/D epitaxial structures 125. In some embodiments, inner spacer structures 130 can be formed between two vertically (e.g., in the z-direction) adjacent NS layers 120. In some embodiments, inner spacer structures 130 can be formed between fin structures 110 and NS layers 120. In some embodiments, inner spacer structures 130 can include a silicon-based dielectric, such as silicon nitride (SiN), silicon oxy-carbon-nitride (SiOCN), silicon carbon-nitride (SiCN), or silicon oxy-nitride (SiON). In some embodiments, inner spacer structures 130 can include a low-k material, such as a porous material and a carbon-rich silicon oxide based dielectrics.

Referring to FIGS. 1 and 2, semiconductor device 100 can include isolation layers 145 disposed on fin structures 110 and below S/D epitaxial structures 125. For S/D epitaxial structures 125 formed in a process involving etching openings with high aspect ratios, bottommost gate structures of gate structures 115 may be formed with less uniform shapes, resulting in less effective control on conductance of fin structures 110 under the bottommost gate structures. As a consequence, leakage current channels 170 may be formed between S/D epitaxial structures 125 through regions of fin structures 110 under bottommost gate electrodes 115cb. The presence of isolation layers 145 below S/D epitaxial structures 125 can effectively block such leakage current channels 170. The presence of isolation layers 145 below S/D epitaxial structures 125 can also block a leakage current and improve a gate capacitance between S/D epitaxial structures 125 and bottommost gate electrodes 115cb. In some embodiments, isolation layers 145 can be in contact with epitaxial regions 253 and 255. In some embodiments, depending on positions of top surfaces 145t of isolation layers 145, isolation layers 145 can be in contact with or be isolated with epitaxial regions 250. In some embodiments, top surfaces 145t can be a flat surface. In some embodiments, top surfaces 145t can be a curved surface, such as a concave or convex surface. In some embodiments, isolation layers 145 can include an oxide material, such as silicon oxide. In some embodiments, isolation layers 145 can be formed in a flowable chemical vapor deposition (FCVD) process. In some embodiments, isolation layers 145 can protrude into fin structures 110. In some embodiments, as shown in FIG. 2, a depth D1 of isolation layers 145 protruding into fin structures 110 can be between about 40 nm and about 60 nm. For example, depth D1 can be between about 50 nm and about 55 nm. In some embodiments, bottom surfaces 145s of isolation layers 145 in contact with fin structures 110 can be curved. In some embodiments, isolation layers 145 can extend above fin structures 110. In some embodiments, as shown in FIG. 2, a height D2 of isolation layers 145 extending above fin structures 110 can be between about 0 nm and about 20 nm. For example, height D2 can be about 5 nm and about 10 nm. Isolation layers 145 can be disposed over side surfaces of bottommost inner spacer structures 130b, as shown in FIG. 2. In some embodiments, a distance L2 between two isolation layers 145 under two S/D epitaxial structures 125 of a GAAFETs 105 can be between about 55 nm and about 250 nm. Distance L2 also corresponds to a horizontal distance between two outer side surfaces of two bottommost inner spacer structures 130b of a GAAFETs 105. Similarly, distance L1 corresponds to a horizontal distance between two outer side surfaces of two opposite inner spacer structures 130 above bottommost inner spacer structures 130b. In some embodiments, distance L1 can be greater than length Lc. In some embodiments, distance L2 can be greater than distance L1, as a result of the above mentioned process involving etching openings with high aspect ratios. In some embodiments, a ratio of distance L1 to distance L2 can be between about 0.8 and about 1.

Referring to FIGS. 1 and 2, semiconductor device 100 can further include gate spacers 135 formed between gate structure 115 and S/D epitaxial structure 125, which can provide structural support during the formation of gate structures 115. In addition, gate spacers 135 can provide gate structures 115 with electrical isolation and protection during the formation of S/D contacts, which are not shown in FIG. 1. Gate spacers 135 can be made of any suitable dielectric material. In some embodiments, gate spacers 135 can be made of silicon oxide, silicon nitride, or a low-k material with a dielectric constant less than about 3.9. In some embodiments, gate spacers 135 can have any suitable thickness, such as from about 5 nm to about 15 nm. Based on the disclosure herein, other materials and thicknesses for gate spacers 135 are within the scope and spirit of this disclosure.

Referring to FIGS. 1 and 2, semiconductor device 100 can further include shallow trench isolation (STI) regions 138 configured to provide electrical isolation between fin structures 110. Also, STI regions 138 can provide electrical isolation between GAAFET 105 and neighboring active and passive elements integrated with or deposited on substrate 102. STI regions 138 can include one or more layers of dielectric material, such as a nitride layer, an oxide layer disposed on the nitride layer, and an insulating layer disposed on the nitride layer. In some embodiments, the insulating layer can include silicon oxide, silicon nitride, silicon oxynitride, fluorine-doped silicate glass (FSG), a low-k dielectric material, and/or other suitable insulating materials. In some embodiments, STI regions 138 can be in contact with isolation layers 145, as shown in FIG. 1. In some embodiments, STI regions 138 and isolation layers 145 can include the same dielectric materials. In some embodiments, STI regions 138 and isolation layers 145 can include different dielectric materials. In some embodiments, an interface between an STI region 138 and a fin structure 110 and an interface between the STI region 138 and an isolation layers 145 can be coplanar. Based on the disclosure herein, other dielectric materials for STI regions 138 are within the scope and spirit of this disclosure.

Referring to FIGS. 1 and 2, semiconductor device 100 can further include interlayer dielectric (ILD) layers 165 to provide electrical isolation to structural elements it surrounds or covers, such as gate structures 115 and S/D epitaxial structures 125. In some embodiments, gate spacers 135 can be formed between gate structures 115 and ILD layers 165. ILD layers 165 can include any suitable dielectric material to provide electrical insulation, such as silicon oxide, silicon dioxide, silicon oxycarbide, silicon oxynitride, silicon oxy-carbon nitride, and silicon carbonitride. ILD layers 165 can have any suitable thickness, such as from about 50 nm to about 200 nm, to provide electrical insulation. Based on the disclosure herein, other insulating materials and thicknesses for ILD layers 165 are within the scope and spirit of this disclosure.

Referring to FIGS. 1 and 2, semiconductor device 100 can further include S/D contacts 163 in contact with S/D epitaxial structures 125. S/D contacts 163 can be disposed on S/D epitaxial structures 125 and surrounded by ILD layers 165. In some embodiments, a height of S/D contacts 163 can be between about 27 nm and about 33 nm. S/D contacts 163 can include any suitable conductive material that provides low contact resistance with S/D epitaxial structures 125. In some embodiments, S/D contacts 163 can be made of polysilicon, titanium nitride, tantalum nitride, tungsten nitride, titanium, aluminum, copper, tungsten, tantalum, copper, or nickel. Based on the disclosure herein, other materials for S/D contacts 163 are within the scope and spirit of this disclosure.

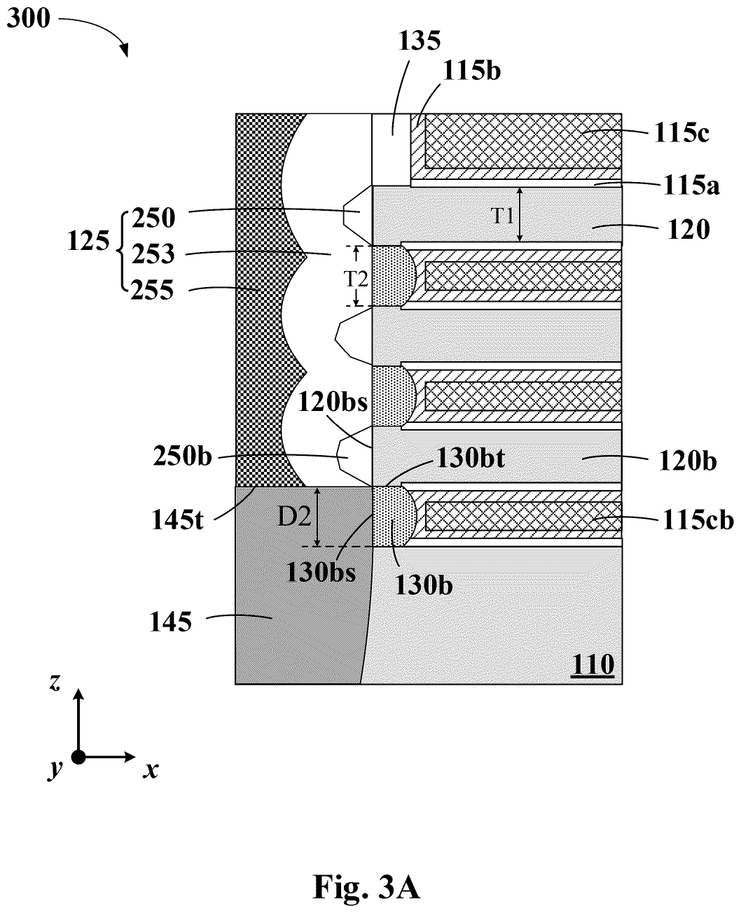

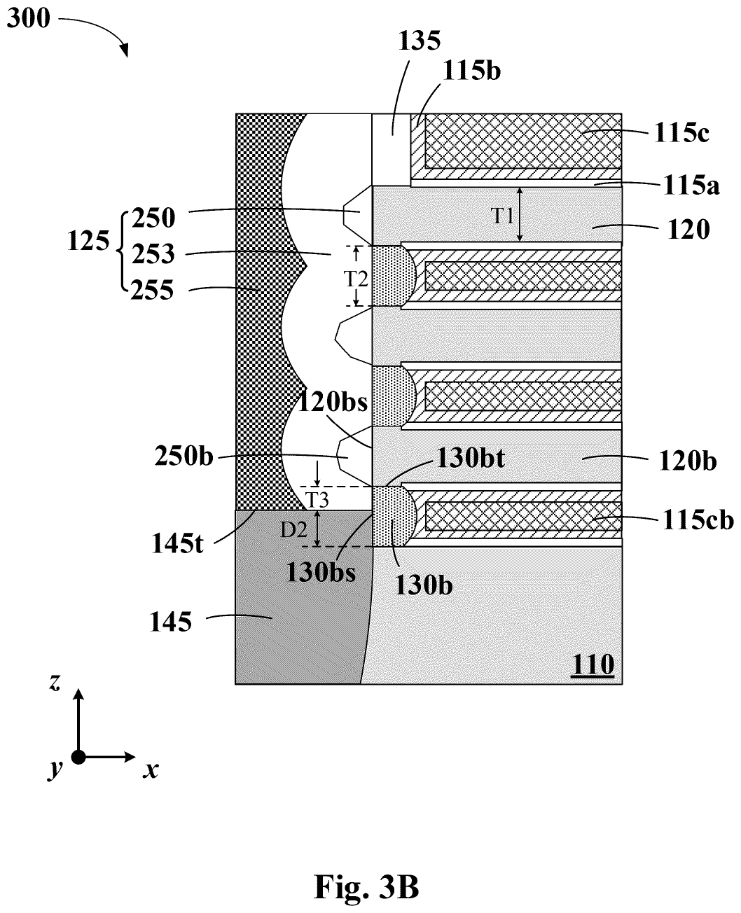

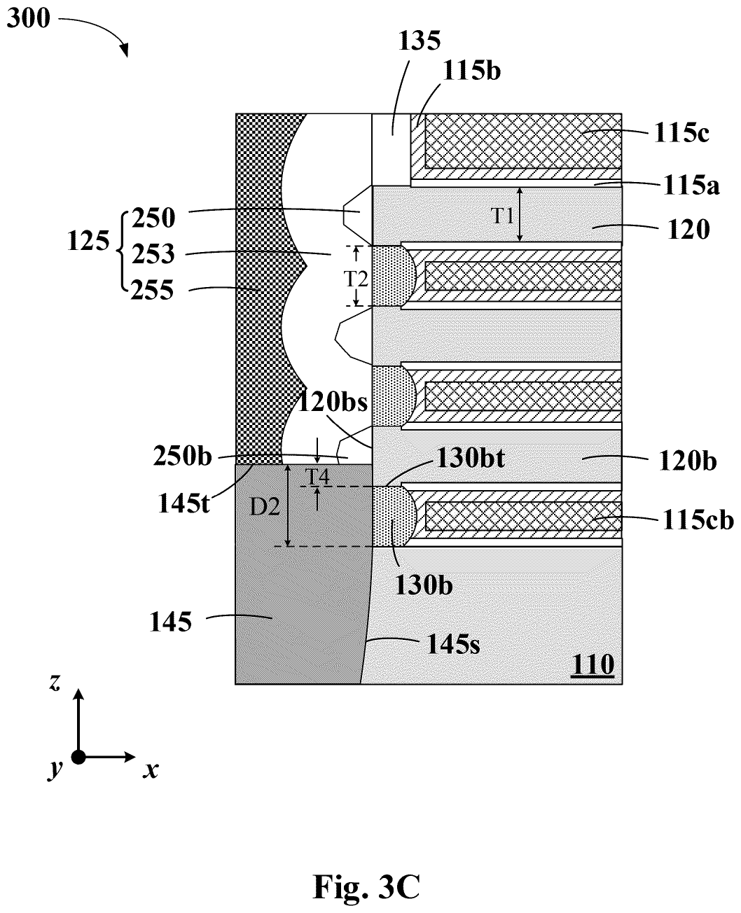

FIGS. 3A-3C illustrate a zoomed-in portion 300 in the cross-sectional view in FIG. 2. FIGS. 3A-3C illustrate embodiments about isolation layers 145 with different heights D2. The discussion of elements in FIGS. 1 and 2 with the same annotations applies to FIGS. 3A-3C, unless mentioned otherwise.

Referring to FIG. 3A, isolation layer 145 can have top surface 145t coplanar with a top surface 130bt of bottommost inner spacer structure 130b. In some embodiments, with top surface 145t coplanar with top surface 130bt, isolation layer 145 can cover an entirety of a side surface 130bs of bottommost inner spacer structure 130b, such that S/D epitaxial structure 125 can be isolated from bottommost inner spacer structure 130b, suppressing a leakage current between S/D epitaxial structure 125 and a bottommost gate electrode 115cb. In some embodiments, with top surface 145t coplanar with top surface 130bt, isolation layer 145 does not cover a side surface 120bs of a bottommost NS layer 120b, and does not reduce a contact area and a contact conductance between S/D epitaxial structure 125 and bottommost NS layer 120b. Top surface 145t can be formed coplanar with top surface 130bt in the process of forming isolation layer 145 by terminating the FCVD process when top surface 145t reaches the same vertical position as top surface 130bt. In some embodiments, with top surface 145t and top surface 130bt coplanar, top surface 145t can be in contact with a bottom end point of a bottommost epitaxial region 250b.

Referring to FIG. 3B, in some embodiments, isolation layer 145 can have top surface 145t below top surface 130bt of bottommost inner spacer structure 130b. For example, a vertical distance T3 from top surface 130bt to top surface 145t can be nonzero. In some embodiments, with vertical distance T3 being nonzero, controlling the forming process of isolation layer 145 can be less demanding in accurately controlling the vertical position of top surface 145t. In some embodiments, a ratio of vertical distance T3 to height D2 can be between about 0 and about 0.5. In some embodiments, if the ratio of vertical distance T3 to height D2 is greater than about 0.5, a contact area between side surface 130bs of bottommost inner spacer structure 130b and S/D epitaxial structure 125 may be too large, such that the leakage current between S/D epitaxial structure 125 and bottommost gate electrode 115cb may not be effectively suppressed. Top surface 145t can be formed below top surface 130bt in the process of forming isolation layer 145 by terminating the FCVD process before top surface 145t reaches the vertical position of top surface 130bt. In some embodiments, with top surface 145t below top surface 130bt, top surface 145t can be isolated with bottommost epitaxial region 250b.

Referring to FIG. 3C, in some embodiments, isolation layer 145 can have top surface 145t above top surface 130bt of bottommost inner spacer structure 130b. For example, a vertical distance T4 from top surface 145t to top surface 130bt can be nonzero, such that isolation layer 145 can be in contact with side surface 120bs of bottommost NS layer 120b. In some embodiments, with vertical distance T4 being nonzero, controlling the forming process of isolation layer 145 can be less demanding in accurately controlling the vertical position of top surface 145t. In some embodiments, a ratio of vertical distance T4 to height D2 can be between about 0 and about 0.2. In some embodiments, if the ratio of vertical distance T4 to height D2 is greater than about 0.2, a contact area between bottommost NS layer 120b and S/D epitaxial structure 125 may be too small, which may compromise the contact conductance between S/D epitaxial structure 125 and bottommost NS layer 120b. Top surface 145t can be formed above top surface 130bt in the process of forming isolation layer 145 by terminating the FCVD process after top surface 145t reaches the vertical position of top surface 130bt. In some embodiments, with top surface 145t above top surface 130bt, top surface 145t can be in contact with a bottom surface of bottommost epitaxial region 250b.

Although the three embodiments of isolation layers 145 presented in FIGS. 3A-3C are different, it is to be understood by those skilled in relevant art(s) that the different features of these embodiments can be included in a single embodiment. For example, a GAAFETs 105 can include a first S/D epitaxial structure 125 on a first isolation layer 145 and a second S/D epitaxial structure 125 on a second isolation layer 145, with (i) a first top surface 145t of the first isolation layer 145 coplanar with a first top surface 130bt of a first bottommost inner spacer structure 130b adjacent to the first isolation layer 145 and (ii) a second top surface 145t of the second isolation layer 145 above or below a second top surface 130bt of a second bottommost inner spacer structure 130b adjacent to the second isolation layer 145. In some embodiments, the first and second isolation layers 145 of GAAFETs 105 can have any combination of the embodiments as shown in FIGS. 3A-3C.

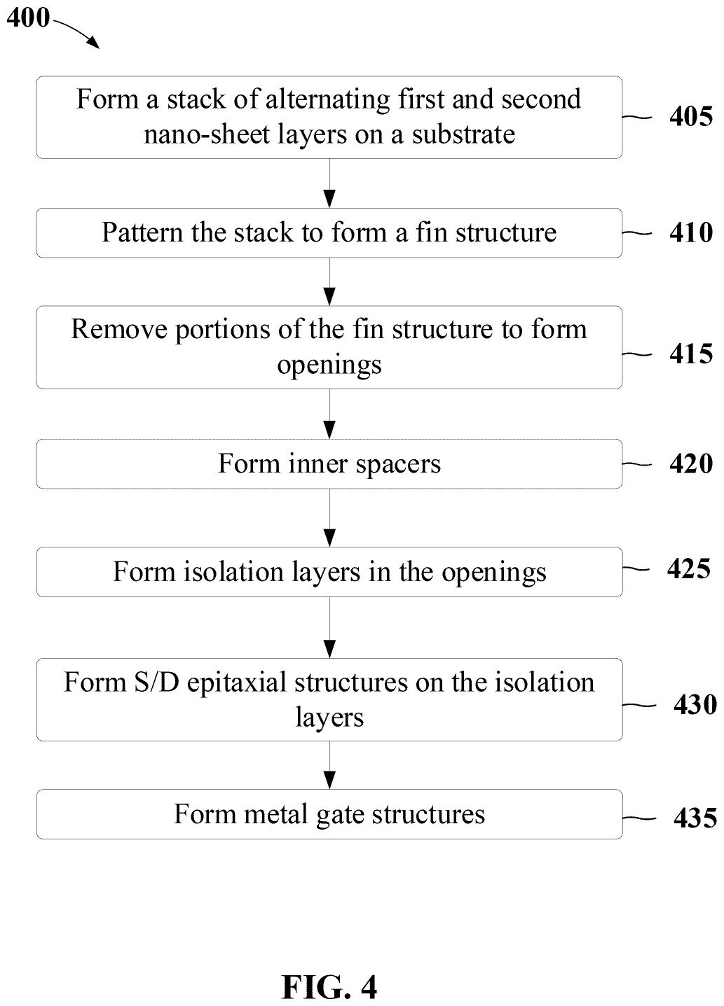

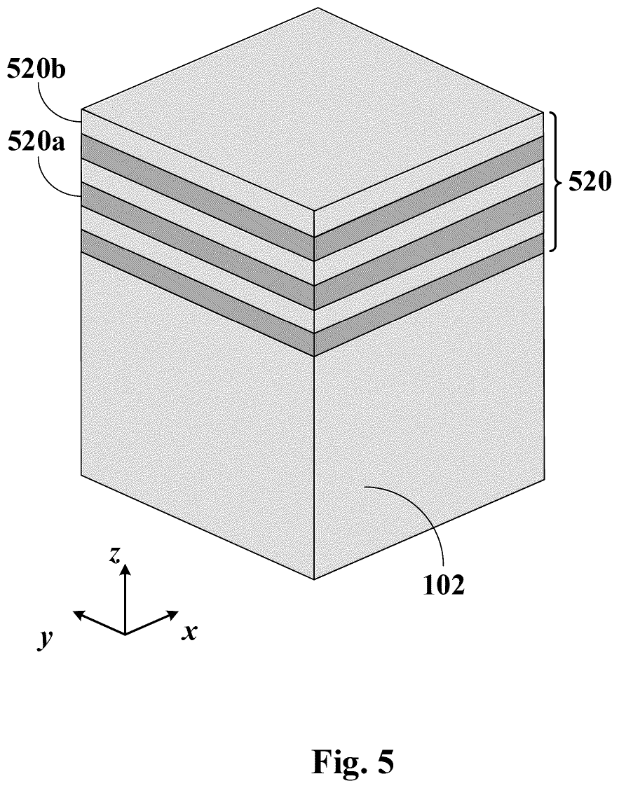

According to some embodiments, FIG. 4 illustrates a flowchart of a fabrication method 400 for the formation of GAAFETs 105 shown in FIGS. 1-3C. This disclosure is not limited to this operational description and additional operations may be performed. Other fabrication operations can be performed between the various operations of method 400 and are omitted merely for clarity. Moreover, not all operations may be needed to perform the disclosure provided herein. Additionally, some of the operations may be performed simultaneously, or in a different order than the ones shown in FIG. 4. In some embodiments, one or more other operations may be performed in addition to or in place of the presently described operations. For illustrative purposes, method 400 is described with reference to the structures shown in FIGS. 5-17. The discussion of elements in FIGS. 1-3C with the same annotations applies to FIGS. 5-17, unless mentioned otherwise.

Referring to FIG. 4, method 400 begins with operation 405 and the process of forming a stack of alternating first and second NS layers on a substrate (e.g., substrate 102). FIG. 5 is an isometric view of substrate 102 after operation 405 and the formation of a stack 520 of alternating first and second NS layers 520a and 520b. In some embodiments, first and second NS layers 520a and 520b are formed on an exposed top surface of substrate 102. In some embodiments, first NS layers 520a are sacrificial NS layers subject to subsequent removal and second NS layers 520b correspond to NS layers 120 shown in FIG. 1. In some embodiments, the material of first NS layers 520a in stack 520 is selected so that first NS layers 520a can be selectively removed via etching from stack 520 without removing second NS layers 520b. For example, first NS layers 520a can be SiGe NS layers and second NS layers 520b can be Si NS layers.

First and second NS layers 520a and 520b can be grown with any suitable method. For example, first and second NS layers 520a and 520b can be grown with a CVD process with precursor gases, like silane (SiH₄), disilane (Si₂H₆), dichlorosilane (SiH₂Cl₂), trichlorosilane (SiHCl₃), germane (GeH₄), digermane (Ge₂H₆), other suitable gases, or combinations thereof. In some embodiments, first NS layers 520a can include Ge with a concentration between about 20% and about 30%, while second NS layers 120 are substantially germanium-free—e.g., have a Ge concentration less than about 1%. In some embodiments, second NS layers 520b, which correspond to NS layers 120 in FIG. 1, form the channel region of GAAFET 105 and can be lightly doped or intrinsic (e.g., un-doped). If lightly doped, the doping level of second NS layers 520b is less than about 1013 atoms/cm³. First and second NS layers 520a and 520b can be sequentially deposited without a vacuum break (e.g., in-situ) to avoid the formation of any intervening layers. In some embodiments, first NS layers 520a can be doped to increase their etching selectivity compared to second NS layers 520b in a subsequent etching operation.

In some embodiments, a thickness of first NS layers 520a controls the spacing between every other second NS layer 520b in stack 520. The thickness of first and second NS layers 520a and 520b can range, for example, from about 3 nm to about 15 nm. Since first and second NS layers 520a and 520b are grown individually, the thickness of each NS layer can be adjusted independently based, for example, on the deposition time. In some embodiments, additional or fewer number of first and second NS layers 520a and 520b can be formed in stack 520. In some embodiments, a total number of NS layers can be 2n, where n is the number of first NS layers 520a or the number of second NS layers 520b in stack 520. In some embodiments, n can be 1, 2, 3, 4, 5, 6, or any integer number greater than 6.

Referring to FIG. 4, method 400 continues with operation 410 and the process of patterning stack 520 to form fin structures. In some embodiments, stack 520 is patterned to form fin structures with a width along the y-direction and a length along the x-direction. The fin structures can be formed by patterning with any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over stack 520 and patterned using a photolithography process. Spacers are formed alongside the patterned sacrificial layer using a self-aligned process. The sacrificial layer is then removed, and the remaining spacers may then be used as masking structures to pattern the fin structures.

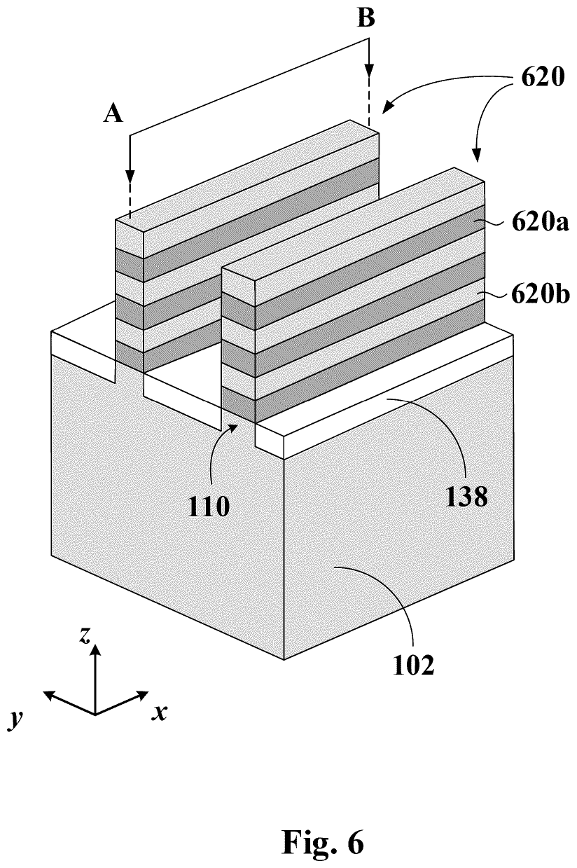

By way of example and not limitation, FIG. 6 is an isometric view of fin structures 620 formed from stack 520 with the aforementioned patterning process in operation 410. In some embodiments, fin structures 620 can be formed by etching first and second NS layers 520a and 520b into first and second NS layers 620a and 620b. In some embodiments, the aforementioned patterning process does not terminate on the top surface of substrate 102 but continues to etch a top portion substrate 102 to form fin structures 110 from substrate 102 under fin structures 620. Since fin structures 620 and fin structures 110 are formed with the same patterning process, fin structures 620 and fin structures 110 are substantially aligned to each other. For example, sidewall surfaces of fin structures 620 in the x-z plane and y-z plane are substantially aligned to respective sidewall surfaces of fin structures 110 as shown in FIG. 6.

Additional fin structures, like fin structures 620, can be formed on substrate 102 in the same or different area of substrate 102. These additional fin structures are not shown in FIG. 6 for simplicity. By way of example and not limitation, each fin structure 620 has a width along the y-direction between about 15 nm and about 150 nm.

In some embodiments, NS layers 620a and 620b are referred to as “nano-sheets” when their width along the y-direction is substantially different from their height along z-direction—for example, when their width is larger/narrower than their height. In some embodiments, NS layers 620a and 620b can also be referred to as “nano-wires” when their width along the y-direction is substantially equal to their height along z-direction. In some embodiments, NS layers 620a and 620b are deposited as nano-sheets and subsequently patterned to form nano-wires with substantially equal height and width. By way of example and not limitation, NS layers 620a and 620b will be described in the context of nano-sheets (NS) layers. Based on the disclosure herein, nano-wires (NW) are within the spirit and the scope of this disclosure. Further, for example purposes and without limiting the scope of this disclosure, first and second NS layers 620a and 620b in method 400 will be described in the context of SiGe and Si NS layers, respectively.

In some embodiments, after the formation of fin structures 620, STI regions 138 can be formed on etched or recessed portions of substrate 102 to cover sidewall surfaces of fin structures 110. In some embodiments, STI regions 138 can electrically isolate fin structures 110 and include one or more silicon oxide based dielectrics. By way of example and not limitation, STI regions 138 can be formed as follows. An isolation structure material (e.g., a silicon oxide based dielectric) is blanket deposited over fin structures 620 and substrate 102. The as-deposited isolation structure material is planarized (e.g., with a chemical mechanical polishing (CMP) process) so that the top surface of the isolation structure material is substantially coplanar with the top surface of fin structures 620. The planarized isolation structure material is subsequently etched back so that the resulting STI regions 138 has a height substantially similar to fin structures 110, as shown in FIG. 6. In some embodiments, fin structures 620 protrudes from STI regions 138 so that STI regions 138 does not cover sidewall portions of fin structures 620 as shown in FIG. 6. This is intentional and facilitates the formation of GAAFETs 105 shown in FIG. 1.

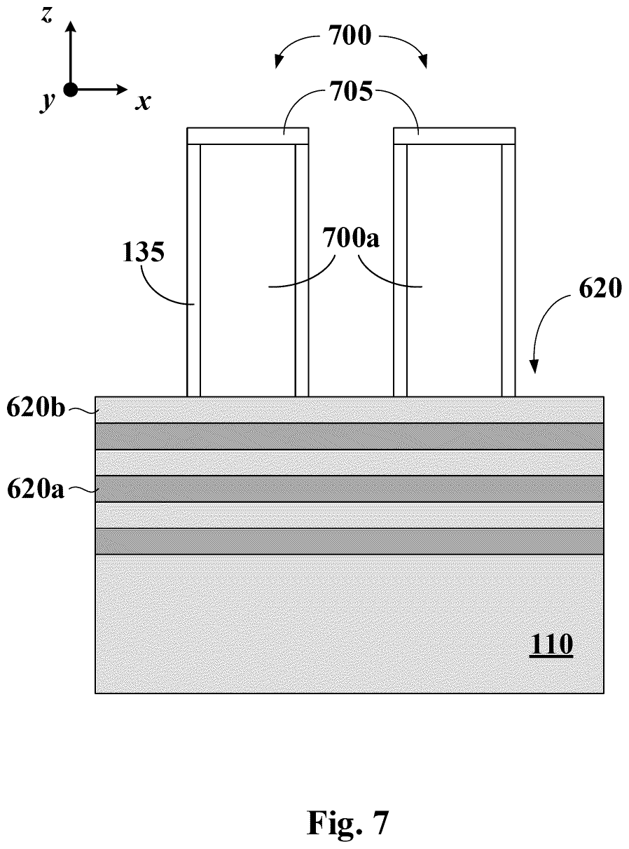

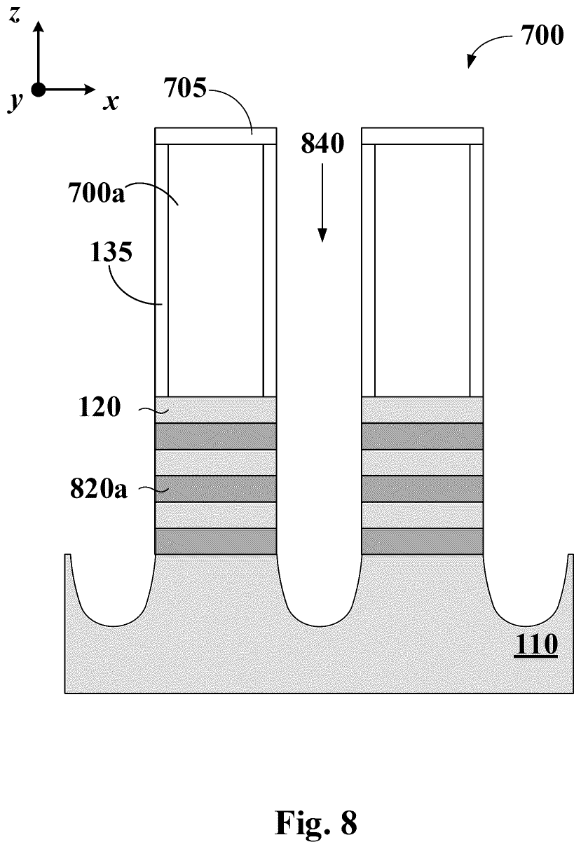

Method 400 continues with operation 415 and the process of removing portions of the fin structures to form openings in the fin structures, including (i) forming sacrificial gate structures 700, as described with reference to FIG. 7 and (ii) removing the portions of fin structure 620 exposed by sacrificial gate structures 700, as described with reference to FIG. 8.

In some embodiments, sacrificial gate structures 700 are formed with their length along the y-direction—e.g., perpendicular to fin structures 620 shown in the isometric view of FIG. 6—and their width along the x-direction. By way of example and not limitation, FIG. 7 is a cross-sectional view of FIG. 6 along cut-line AB. FIG. 7 shows sacrificial gate structures 700 formed on portions of fin structures 620. Because FIG. 7 is a cross-sectional view, as opposed to an isometric view, portions of sacrificial gate structures 700 covering sidewall portions of fin structures 620 are not shown. Further, in the cross-sectional view of FIG. 7, only one of fin structures 620 from FIG. 6 is shown. In some embodiments, portions of sacrificial gate structures 700 are formed between fin structures 620 and on STI regions 138 shown in FIG. 6.

In some embodiments, sacrificial gate structures 700 can cover top and sidewall portions of fin structures 620. Sacrificial gate structures 700 are subsequently replaced with gate structures 115 shown in FIG. 1 during a gate replacement process. Sacrificial gate structures 700 can include a sacrificial gate electrode 700a formed on a sacrificial gate dielectric not shown in FIG. 7 for simplicity. Sacrificial gate structures 700 can also include capping layers 705 formed on top surfaces of sacrificial gate structures 700. In some embodiments, capping layers 705 can protect sacrificial gate electrode 700a from subsequent etching operations. At this fabrication stage, gate spacers 135 can be formed on side surfaces of sacrificial gate structures 700. As discussed above, gate spacers 135 are not removed during the gate replacement process; instead, gate spacers 135 facilitate the formation of gate structures 115 as shown in FIG. 1.

By way of example and not limitation, sacrificial gate structures 700 can be formed by depositing and patterning sacrificial gate electrode 700a over fin structures 620. In some embodiments, sacrificial gate structures 700 are formed over multiple fin structures 620. As shown in FIG. 7, portions of fin structures 620 are not covered by sacrificial gate structures 700. This is because the width of sacrificial gate structures 700 is narrower than the length of fin structures 620 along the x-direction. In some embodiments, sacrificial gate structures 700 are used as masking structures in subsequent etching operations to define the channel region of GAAFETs 105 shown in FIG. 1. For this reason, the lateral dimensions (e.g., the width and length) of sacrificial gate structures 700 and gate structures 115 are substantially similar.

Referring to FIG. 8, portions of fin structures 620 not covered by sacrificial gate structures 700 can be removed. In some embodiments, the removal process involves a dry etching process, a wet etching process, or combinations thereof. The removal process is selective towards first NS layers 620a and second NS layers 620b, shaping them into first NS layers 820a and NS layers 120, respectively. The removal process can further remove portions of fin structure 110. In some embodiments, the dry etching process includes etchants having an oxygen-containing gas, a fluorine-containing gas (e.g., carbon tetrafluoride (CF₄), sulfur hexafluoride (SF₆), difluoromethane (CH₂F₂), trifluoromethane (CHF₃), and/or hexafluorocthane (C₂F₆)); a chlorine-containing gas (e.g., chlorine (Cl₂), chloroform (CHCl₃), carbon tetrachloride (CCl₄), and/or boron trichloride (BCl₃)); a bromine-containing gas (e.g., hydrogen bromide (HBr) and/or bromoform (CHBr₃)); an iodine-containing gas; other suitable etching gases and/or plasmas; or combinations thereof. The wet etching chemistry can include diluted hydrofluoric acid (DHF), potassium hydroxide (KOH) solution, ammonia; a solution containing hydrofluoric acid (HF), nitric acid (HNO₃), acetic acid (CH₃COOH); or combinations thereof.

In some embodiments, the etchants of the aforementioned etching process do not substantially etch sacrificial gate structures 700—which is protected by capping layers 705 and gate spacers 135—and STI regions 138 shown in FIG. 6. This is because capping layers 705, gate spacers 135, and STI regions 138 include materials with a low etching selectivity, such as a silicon nitride based material (e.g., silicon nitride, silicon carbon nitride, and silicon carbon oxy-nitride) or silicon oxide based materials. In some embodiments, STI regions 138 shown in FIG. 6 are used as an etch stop layer for the etching process described above.

Duc to operation 415, openings 840 are formed in each fin structure 620 as shown in FIG. 8. Openings 840 divide each fin structure 620 into separate portions, with each portion covered by a sacrificial gate structure 700. In some embodiments, the removal process in operation 415 can further include removing portions of fin structure 110 uncovered by remaining portions of fin structure 620 and forming curved surfaces of openings 840 on fin structure 110. Removing the portions of fin structure 110 can include etching the portions of fin structure 110 in a similar way as etching the portions of fin structures 620 not covered by sacrificial gate structures 700.

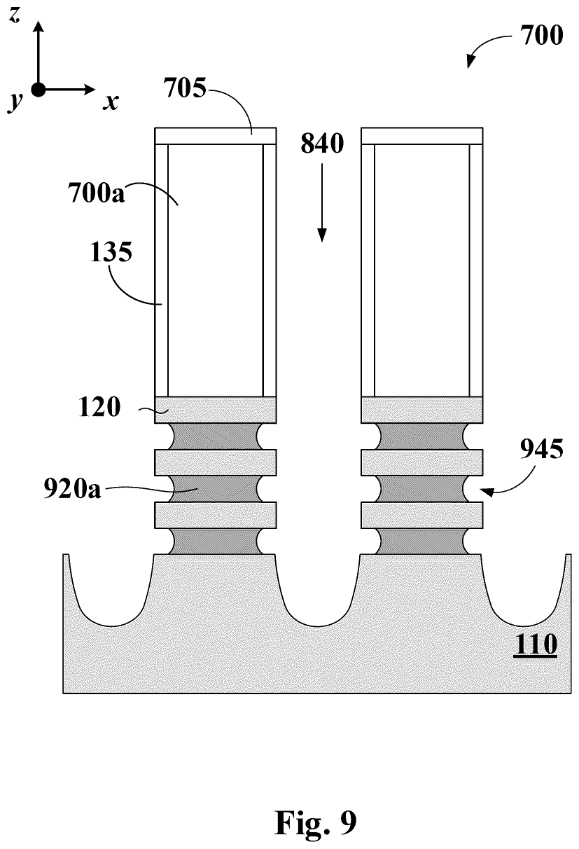

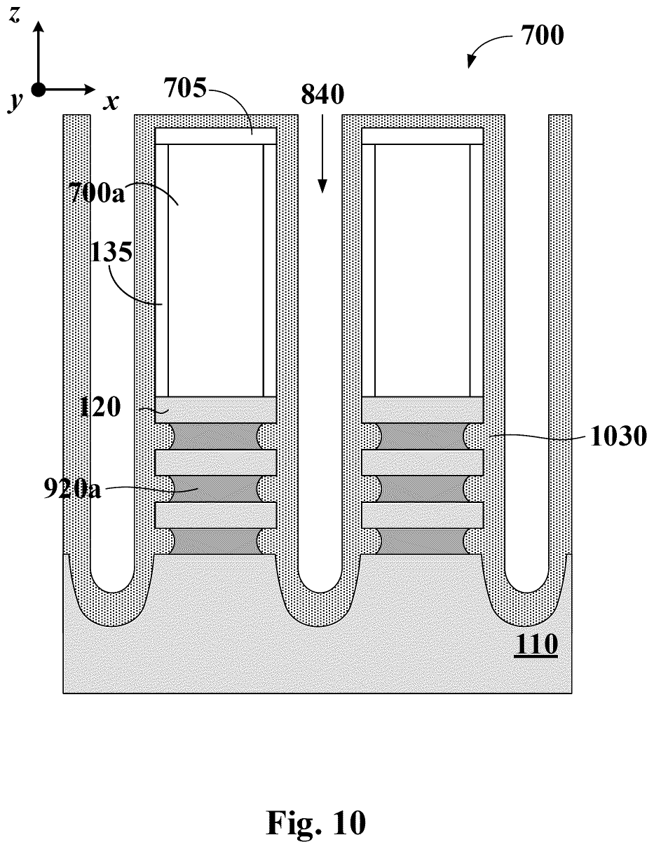

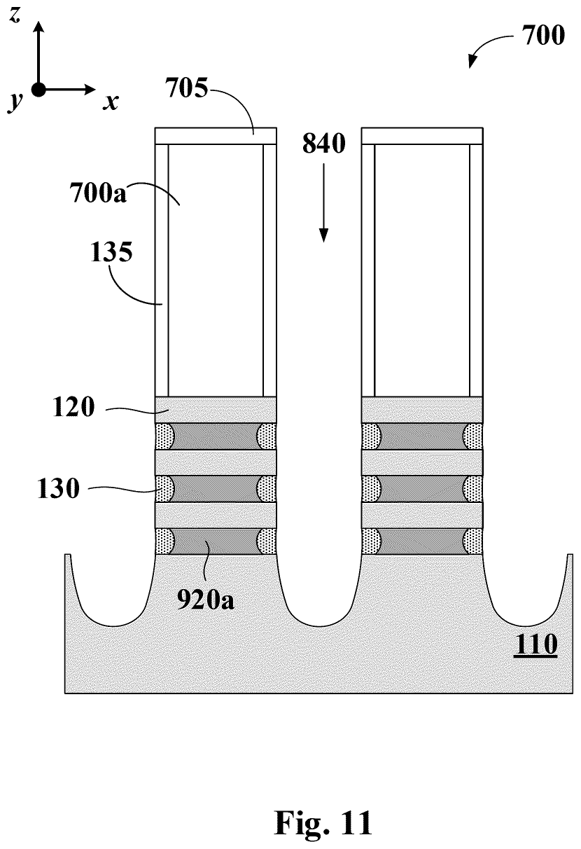

Referring to FIG. 4, method 400 continues with operation 420 and the process of forming inner spacers. The process of forming inner spacers can include (i) selectively etching edge portions of first NS layers 820a to form recessed structures 945, as described with reference to FIG. 9, (ii) depositing a dielectric material to fill the recessed structures 945, as described with reference to FIG. 10, and (iii) removing the dielectric material outside recessed structures 945, as described with reference to FIG. 11. According to some embodiments, FIG. 9 shows the structure of FIG. 8 after exposed edges of first NS layers 820a are laterally etched (e.g., recessed) along the x-direction and turned into first NS layers 920a. According to some embodiments, exposed edges of first NS layers 820a are recessed (e.g., partially etched) by an amount that ranges from about 3 nm to about 10 nm along the x-direction as shown in FIG. 9 to form recessed structures 945.

In some embodiments, the selective etching of first NS layers 820a can be achieved with a dry etching process selective towards SiGe. For example, halogen-based chemistries exhibit a high etching selectivity towards Ge and a low etching selectivity towards Si. Therefore, halogen gases etch Ge-containing layers, such as first NS layers 820a, at a higher etching rate than substantially Ge-free layers like NS layers 120. In some embodiments, the halogen-based chemistries include fluorine-based and/or chlorine-based gasses. Alternatively, a wet etching chemistry with high selectivity towards SiGe can be used. By way of example and not limitation, a wet etching chemistry may include a mixture of sulfuric acid (H₂SO₄) and hydrogen peroxide (H₂O₂) (SPM), or a mixture of ammonia hydroxide with H₂O₂ and water (APM). The aforementioned etching processes are timed so that the desired amount of SiGe is removed.

In some embodiments, first NS layers 820a with a higher Ge atomic concentration have a higher etching rate than NS layers 120 with a lower or zero Ge atomic concentration. Therefore, the etching rate of the aforementioned etching processes can be adjusted by modulating the Ge atomic concentration (e.g., the Ge content) in first NS layers 820a. As discussed above, the Ge content in first NS layers 820a can range between about 20% and about 30%. A SiGe nano-sheet layer with about 20% Ge can be etched slower than a SiGe nano-sheet layer with about 30% Ge. Consequently, the Ge concentration can be adjusted accordingly to achieve the desired etching rate and selectivity between first NS layers 820a and NS layers 120.

Referring to FIGS. 9-11, inner spacer structures 130 can be formed in recessed structures 945. In some embodiments, forming inner spacer structures 130 can include (i) blanket depositing a dielectric layer 1030 with a thickness between about 2 nm and about 7 nm over the entire structure of FIG. 9, as described with reference to FIG. 10 and (ii) removing the portion of the dielectric layer 1030 outside recessed structures 945, leaving inner spacer structures 130 behind filling recessed structures 945, as described with reference to FIG. 11.

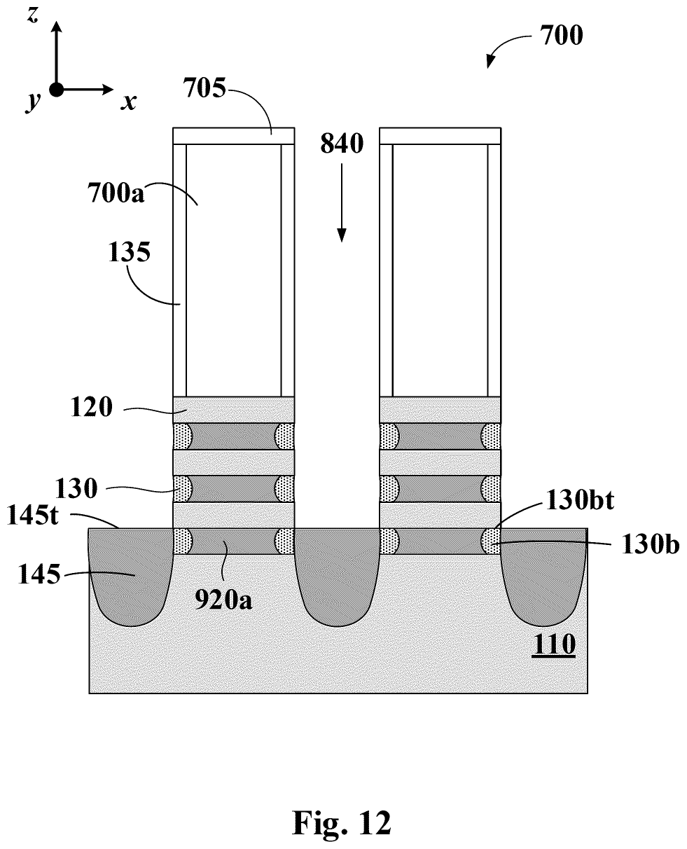

Referring to FIGS. 4, method 400 continues with operation 425 and the process of forming isolation layers in the openings. As described with reference to FIG. 12, isolation layer 145 can be deposited on the bottom surface of opening 840 to fill the space left by the removal of the portions of fin structure 110. In some embodiments, isolation layer 145 can be deposited until top surface 145t of isolation layer 145 is above fin structure 110. For example, isolation layer 145 can be deposited until top surface 145t reaches about similar or about the same vertical position of top surface 130bt of bottommost inner spacer structures 130b, as shown by embodiments in FIGS. 3A-3C.

In some embodiments, isolation layer 145 can be formed by forming a layer of silicon oxide. In some embodiments, isolation layer 145 can be formed by performing a flowable CVD (FCVD) process. In the FCVD process, flowable dielectric materials instead of silicon oxide are deposited. Flowable dielectric materials, as their name suggests, can “flow” during deposition to fill gaps or spaces (such as opening 840) with a high aspect ratio. In the FCVD process, various chemistries can be added to silicon-containing precursors to allow the deposited film to flow. In some embodiments, nitrogen hydride bonds can be added. Examples of flowable dielectric precursors, particularly flowable silicon oxide precursors, include a silicate, a siloxane, a methyl silsesquioxane (MSQ), a hydrogen silsesquioxane (HSQ), an MSQ/HSQ a perhydrosilazane (TCPS), a perhydro-polysilazane (PSZ), a tetraethyl orthosilicate (TEOS), or a silylamine, such as trisilylamine (TSA). These flowable silicon oxide materials are formed in a multiple-operation process. After the flowable film is deposited, it is cured and then annealed to remove undesired element(s) to form silicon oxide at the bottom surface of the gaps or spaces. When the undesired element(s) is removed, the flowable film densities and shrinks. In some embodiments, multiple anneal operations are conducted. The flowable film is then cured and annealed.

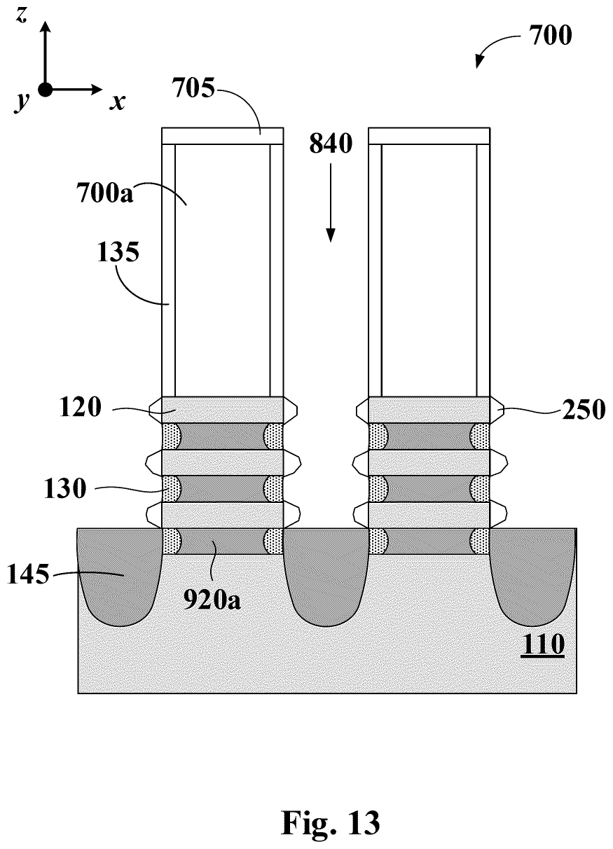

Referring to FIGS. 4, method 400 continues with operation 430 and the process of forming S/D epitaxial structure on the isolation layers and in the openings. For example, as described with reference to FIGS. 13-15, S/D epitaxial structure 125 can be formed by sequentially growing epitaxial regions 250, 253, and 255 in opening 840.

In some embodiments, as described with reference to FIG. 13, epitaxial regions 250 can be epitaxially grown with a CVD process similar to the one used in operation 405 to form first and second NS layers 520a and 520b, as described with reference to FIG. 5. In some embodiments, epitaxial regions 250 can be epitaxially grown on side surfaces of second NS layers 120 in a horizontal direction (e.g., along the x-axis). In some embodiments, epitaxial regions 250 can be grown using a plasma-enhanced CVD (PECVD) process. In some embodiments, precursor gases (e.g., SiH₄, SiH₂Cl₂, SiHCl₃, and/or a combination thereof) can be used to grow a semiconductor material (e.g., Si) having a crystalline structure the same as or similar to the crystalline structure of NS layers 120. In some embodiments, etching gases (e.g., hydrogen chloride (HCl)) can be used to selectively remove the semiconductor material with an amorphous structure formed on dielectric surfaces (e.g., side surfaces of inner spacer structures 130 and gate spacers 135 or top surfaces 145t of isolation layers 145. Removing the semiconductor material with the amorphous structure can ensure that the crystal structure of epitaxial regions 250 is crystalline. In some embodiments, dopant precursor gases, such as phosphanes (PH₃), arsanes (AsH₃), stibane (SbH₃), and/or a combination thereof can be used in the CVD process or the PECVD process to dope epitaxial regions 250.

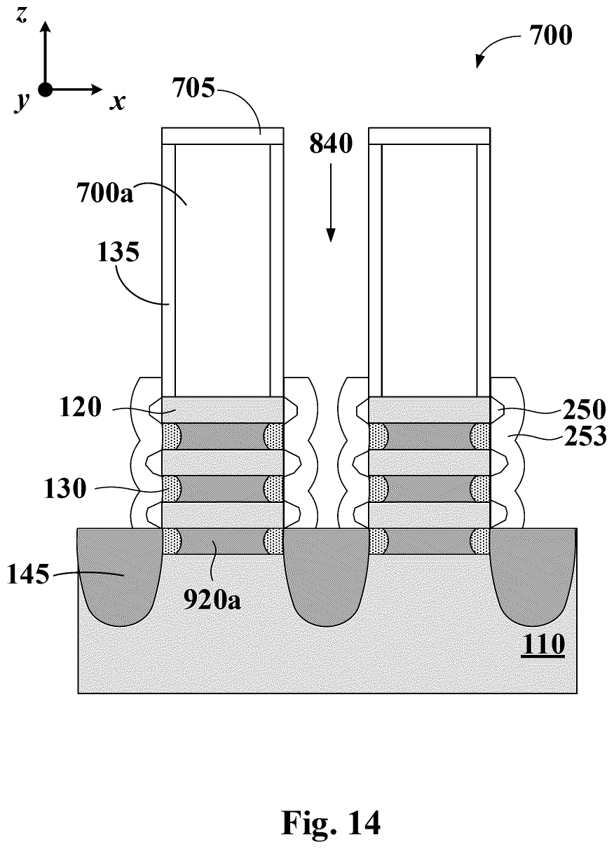

In some embodiments, as described with reference to FIG. 14, epitaxial regions 253 can be formed on exposed side surfaces of epitaxial regions 250. The description of the process of forming epitaxial regions 250 applies to a process of forming epitaxial regions 253, unless otherwise mentioned. In some embodiments, epitaxial regions 253 can be epitaxially grown over side surfaces of epitaxial regions 250 towards both the horizontal and vertical directions (e.g., the x-axis and the z-axis). In some embodiments, epitaxial regions 253 can be formed to be in contact with top surfaces 145t of isolation layers 145. In some embodiments, epitaxial regions 253 can be doped to have a dopant concentration greater than that of epitaxial regions 250. In some embodiments, a time and/or a growing rate of growing epitaxial regions 253 can be controlled to ensure that epitaxial regions 253 grown from epitaxial regions 250 on each side of opening 840 can sufficiently extend in the vertical direction (e.g., along the z-axis) and join together.

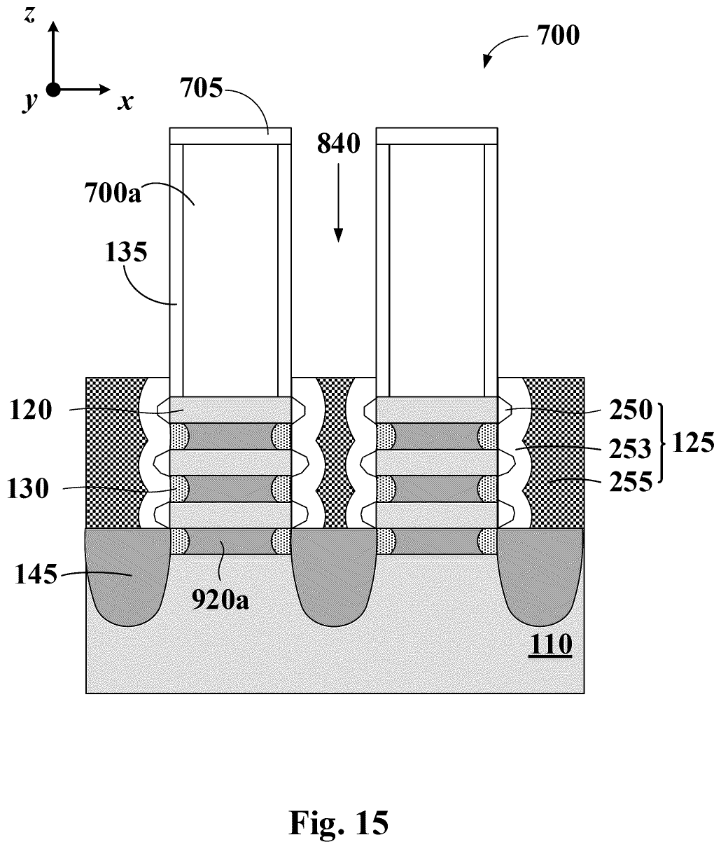

In some embodiments, as described with reference to FIG. 15, epitaxial regions 255 can be formed on exposed side surfaces of epitaxial regions 253. The description of the process of forming epitaxial regions 250 and/or 253 applies to a process of forming epitaxial regions 255, unless otherwise mentioned. In some embodiments, epitaxial regions 255 can be doped to have a dopant concentration greater than that of epitaxial regions 253. In some embodiments, a time and/or a growing rate of growing epitaxial regions 255 can be controlled to ensure that epitaxial regions 255 grown from epitaxial regions 253 on opposite sides of opening 840 can sufficiently extend in the horizontal direction (e.g., along the x-axis) and join together.

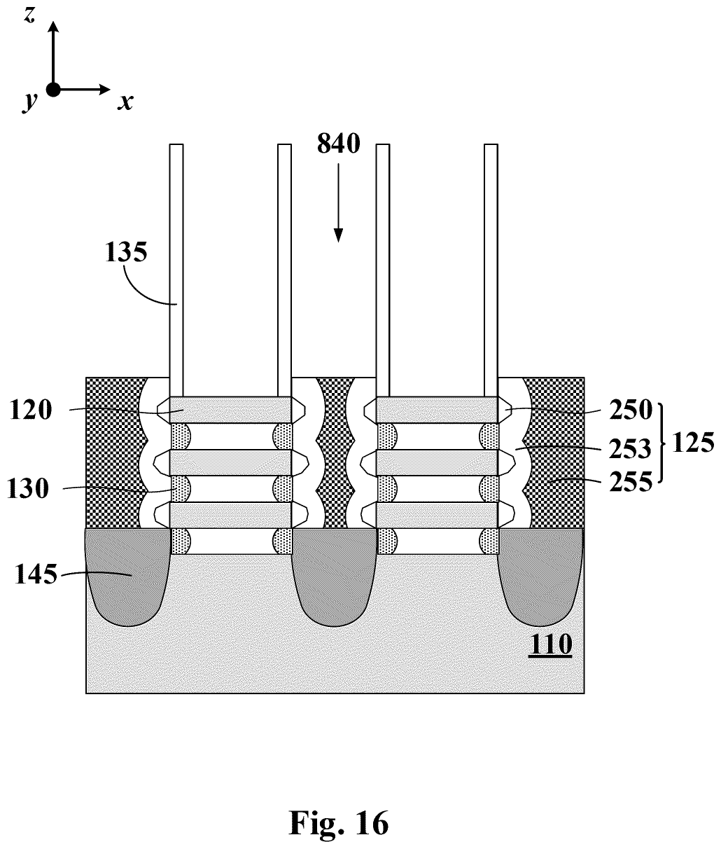

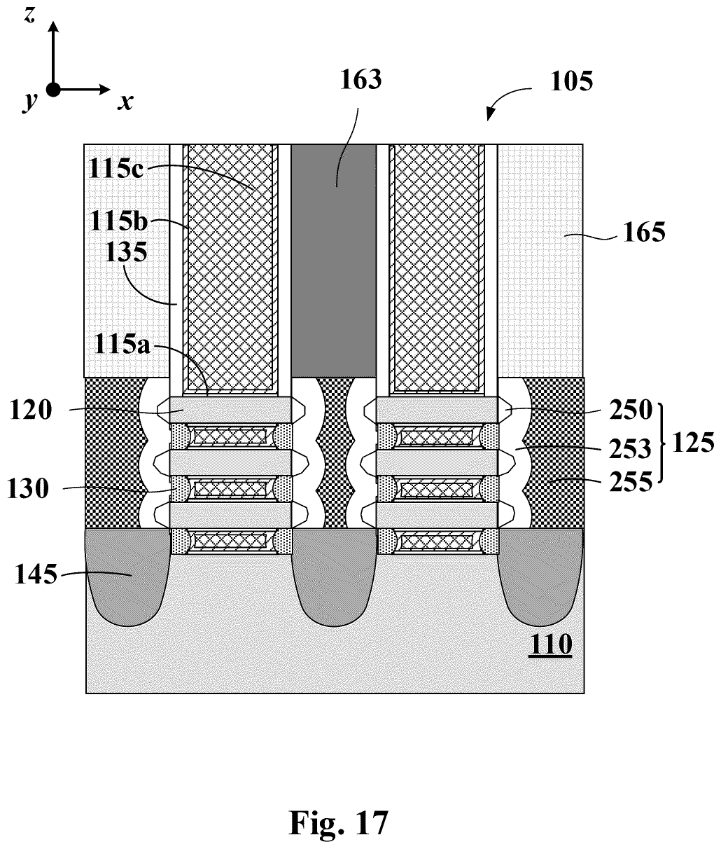

Referring to FIG. 4, method 400 continues with operation 435 and the process of forming metal gate structures. The process of forming metal gate structures can include (i) removing sacrificial gate structures 700 and first NS layers 920a, as described with reference to FIG. 16, and (ii) forming metal gate structures 115 to surround second NS layers 120, as described with reference to FIG. 17.

In some embodiments, removing sacrificial gate structures 700 can include removing capping layer 705 to expose sacrificial gate electrode 700a, and subsequently, removing sacrificial gate electrode 700a to expose fin structures 620 between S/D epitaxial structures 125. In some embodiments, removing first NS layers 920a can include selectively etching first NS layers 920a without removing NS layers 120 as described with reference to FIG. 16.

In some embodiments, forming metal gate structures 115 can include (i) forming interfacial dielectric layer 115a on exposed surfaces of second NS layers 120, (ii) forming gate dielectric layer 115b on interfacial dielectric layer 115a, and (iii) forming gate electrode 115c on gate dielectric layer 115b, as described with reference to FIG. 17. As discussed above, metal gate structures 115 are electrically isolated from S/D epitaxial structures 125 by inner spacer structures 130 and gate spacers 135. In some embodiments, after forming metal gate structures 115, ILD layer 165 can be formed to fill the space above S/D epitaxial structures 125 and S/D contacts 163 can be formed through ILD layer 165 and in contact with S/D epitaxial structures 125.

The embodiments described herein are directed to a structure of a gate-all-around field effect transistors (GAAFET) on a substrate and a method of forming the structure. The structure includes isolation layers below S/D epitaxial structures of the GAAFET. The isolation layers include silicon oxide and are formed by a flowable chemical vapor deposition process. The isolation layers are disposed over side surfaces of bottommost inner spacer structures of the GAAFET and protrude into the substrate. The isolation layers suppress a leakage current through the substrate between opposite S/D epitaxial structures. The isolation layers also suppress a leakage current through the bottommost inner spacer structures between a gate structure of the GAAFET and the S/D epitaxial structures.

In some embodiments, a structure includes nanostructure element formed on a substrate, a gate structure surrounding the nanostructure element, and an inner spacer structure abutting (or in contact with) the gate structure. The structure further includes a source/drain region in contact with a side surface of the nanostructure element and an isolation layer below the source/drain region and in contact with a side surface of the inner spacer structure.

In some embodiments, a structure includes nano-sheet layers formed on a substrate, a gate structure surrounding the nano-sheet layers, and inner spacers in contact with the gate structure. The structure further includes an isolation layer over a side surface of a bottommost inner spacer and a source/drain structure on the isolation layer and in contact with the nano-sheet layers.

In some embodiments, a method includes forming a stack of channel layers alternately stacked with sacrificial layers on a substrate, forming an opening through the stack and into the substrate, removing a portion of each of the sacrificial layers exposed in the opening to form recess structures, forming inner spacers in the recess structures, forming an isolation layer over a bottom surface of the opening and over a side surface of a bottommost inner spacer, and forming an epitaxial region on the isolation layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a nanostructure element on a substrate;
a gate structure surrounding the nanostructure element;
an inner spacer structure abutting the gate structure and under the nanostructure element;
a source/drain (S/D) region in contact with a side surface of the nanostructure element; and
an isolation layer below the S/D region and in contact with a side surface of the inner spacer structure.

2. The structure of claim 1, wherein a top surface of the isolation layer is coplanar with an interface between the inner spacer structure and the nanostructure element.

3. The structure of claim 1, wherein a top surface of the isolation layer is above a bottom surface of the inner spacer structure.

4. The structure of claim 1, wherein the isolation layer comprises silicon oxide.

5. The structure of claim 1, wherein a bottom surface of the S/D region is coplanar with a bottom surface of the nanostructure element.

6. The structure of claim 1, wherein the S/D region comprises:
a first epitaxial layer over the side surface of the nanostructure element; and
a second epitaxial layer over a convex surface of the first epitaxial layer.

7. The structure of claim 6, wherein the first and second epitaxial layers are in contact with the isolation layer.

8. A structure, comprising:
a plurality of nano-sheet layers on a substrate;
a gate structure surrounding the plurality of nano-sheet layers;
a plurality of inner spacers in contact with the gate structure;
an isolation layer over a side surface of a bottommost inner spacer of the plurality of inner spacers; and
a source/drain (S/D) structure on the isolation layer and in contact with the plurality of nano-sheet layers.

9. The structure of claim 8, wherein a top surface of the isolation layer is coplanar with a top surface of the bottommost inner spacer.

10. The structure of claim 8, wherein the isolation layer protrudes into the substrate.

11. The structure of claim 8, wherein an interface between the isolation layer and the substrate is curved.

12. The structure of claim 8, wherein the S/D structure is isolated from the bottommost inner spacer.

13. The structure of claim 8, further comprising:
an other isolation layer over a side surface of an other bottommost inner spacer of the plurality of inner spacers; and
an other S/D structure below the other isolation layer, wherein the plurality of nano-sheet layers is between the S/D structure and the other S/D structure, and wherein a distance between the isolation layer and the other isolation layer is greater than a distance between the S/D structure and the other S/D structure.

14. A method, comprising:
forming, on a substrate, a stack of a plurality of channel layers alternately stacked with a plurality of sacrificial layers;
forming an opening through the stack and into the substrate;
removing a portion of each of the plurality of sacrificial layers exposed in the opening to form a plurality of recess structures;
forming a plurality of inner spacers in the plurality of recess structures;
forming an isolation layer over a bottom surface of the opening and over a side surface of a bottommost inner spacer of the plurality of inner spacers; and
forming an epitaxial region on the isolation layer.

15. The method of claim 14, wherein forming the isolation layer comprises performing a flowable chemical vapor deposition to deposit an oxide material at the bottom surface of the opening without depositing the oxide material on side surfaces of the plurality of channel layers.

16. The method of claim 14, wherein forming the isolation layer comprises depositing an oxide material until a top surface of the isolation layer is coplanar with a top surface of the bottommost inner spacer.

17. The method of claim 14, wherein forming the epitaxial region comprises forming a plurality of epitaxial layers on exposed side surfaces of the plurality of channel layers.

18. The method of claim 17, wherein forming the epitaxial region further comprises:
forming a first continuous epitaxial layer connecting a half of the plurality of epitaxial layers on a first side of the opening; and
forming a second continuous epitaxial layer connecting another half of the plurality of epitaxial layers on a second side of the opening.

19. The method of claim 18, wherein forming the epitaxial region further comprises forming a vertical epitaxial layer connecting the first and second continuous epitaxial layers.

20. The method of claim 14, further comprising replacing the plurality of sacrificial layers with a gate structure surrounding the plurality of channel layers.
